(19) United States
(12) Patent Application Publication
(10) Pub. No.: US 2026/0026368 A1
(43) Pub. Date: Jan. 22, 2026

(54) SEMICONDUCTOR DIE WITH BOND PAD FORMED FROM NANOWIRES

(71) Applicant: Infineon Technologies AG, Neubiberg (DE)

(72) Inventors: Christoph Bayer, Eußenheim (DE); Maik Lohmann, Soest (DE); Fabian Craes, Soest (DE)

(21) Appl. No.: 18/776,828

(22) Filed: Jul. 18, 2024

(51) Int. Cl. H01L 23/00; H01L 23/498

(52) U.S. Cl. CPC H01L 24/05; H01L 23/498; H01L 24/48; H01L 24/85; H01L 2224/04042; H01L 2224/0555; H01L 2224/05578; H01L 2224/45147; H01L 2224/48225; H01L 2224/85048

(57) ABSTRACT

A method of forming a semiconductor package includes providing a semiconductor die that includes a bond pad disposed at an upper side of the semiconductor die, providing a carrier that includes a die attach pad and a landing pad, mounting the semiconductor die on the die attach pad with the bond pad facing away from the carrier, and attaching an electrical interconnect element between the bond pad and the landing pad, wherein the bond pad is formed from nanowires.

### BACKGROUND

In the field of the semiconductor devices, metallization layers are widely used for forming interconnect lines between devices and for forming bond pads. In the field of power devices, thicker metallization layers are needed to accommodate the large currents and heat associated with power device operation. Increasing the thickness of a metallization layer on a semiconductor die creates several design challenges. Specifically, as the metallization thickness increases, so does the risk of delamination from the substrate, cracking and wafer bow. Moreover, it is desirable to use interconnect elements made from copper to accommodate the large currents and heat associated with power device operation. However, copper interconnect elements can damage the bond pads, due to the harness of material and force needed to effectuate attachment. Accordingly, there is a need to improve the durability of metallization layers in semiconductor devices.

### SUMMARY

A method of forming a semiconductor package is disclosed. According to an embodiment, the method comprises providing a semiconductor die that comprises a bond pad disposed at an upper side of the semiconductor die, providing a carrier that comprises a die attach pad and a landing pad, mounting the semiconductor die on the die attach pad with the bond pad facing away from the carrier, and attaching an electrical interconnect element between the bond pad and the landing pad, wherein the bond pad is formed from nanowires.

A semiconductor package is disclosed. According to an embodiment, the semiconductor package comprises a carrier that comprises a die attach pad and a landing pad die, a semiconductor die that comprises a bond pad disposed at an upper side of the semiconductor die and is mounted on the die attach pad with the bond pad facing away from the carrier, and an electrical interconnect element attached between the bond pad and the landing pad, wherein the bond pad is formed from nanowires.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 illustrates an assembly for forming a semiconductor package, according to an embodiment.

FIG. 2 illustrates an assembly for forming a semiconductor package, according to an embodiment.

FIG. 3 illustrates an assembly for forming a semiconductor package, according to an embodiment.

### DETAILED DESCRIPTION

Embodiments of a semiconductor package and corresponding method of forming the semiconductor package are disclosed herein. The semiconductor package comprises a semiconductor die mounted on a carrier, e.g., a power electronics substrate, PCB, lead frame, etc. The semiconductor die comprises a bond pad disposed at an upper side of the semiconductor die that faces away from the carrier. An electrical interconnect element, e.g., bond wire, clip, ribbon, etc., is used to form an electrical connection between the bond pad and a landing pad of the carrier. Advantageously, the bond pad of the semiconductor die is formed of nanowires. The nanowire bond pad configuration facilitates improved current capacity and heat dissipation, while avoiding some of the drawbacks of conventional metallization layers at increased thickness values. Due to the compressibility and elasticity of the bond pad structure, wafer bow and cracking are mitigated in comparison to conventional metallization layers. Moreover, thick and/or hard interconnect elements, such as copper bond wires, can be used with a pressure-based attachment technique can be used with reduced risk of cracking the bond pad.

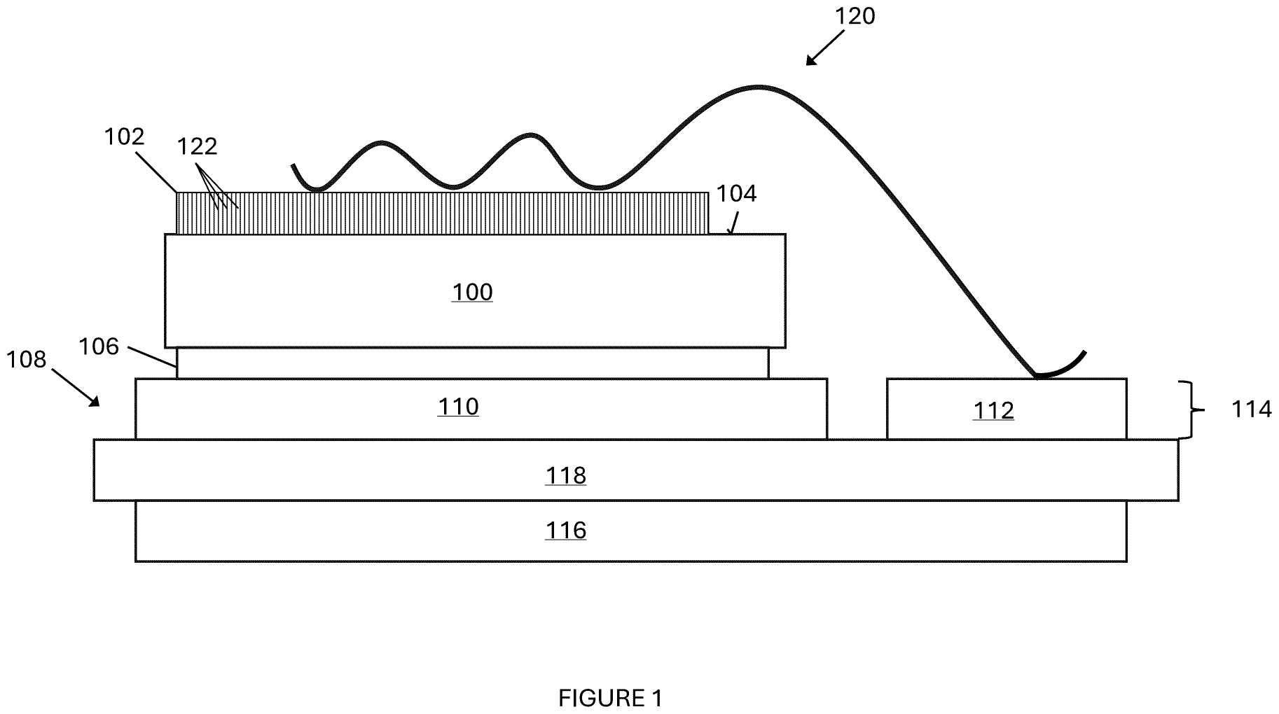

Referring to FIG. 1, a method of forming a semiconductor package comprises providing a semiconductor die 100 that comprises a bond pad 102 disposed at an upper side 104 of the semiconductor die 100. According to an embodiment, the semiconductor die 100 is a power device. The term power device refers to a discrete semiconductor die 100 that is rated to accommodate voltages and/or currents associated with power applications, e.g., voltages of at least 100 V (volts), at least 600 V, at least 1200V or more and/or rated to accommodate currents of at least 1 A (amperes), at least 10 A, at least 50 A, at least 100 A or more. Power devices include power transistors, e.g., MOSFETs, HEMTs, IGBTs, etc., thyristors and diodes. The bond pad 102 is configured as a point of electrical contact to one of the terminals from the device incorporated into the semiconductor die 100. According to an embodiment, the bond pad 102 is configured as a load terminal, i.e., a terminal that accommodates the load current of the device. For example, the bond pad 102 may correspond to a source or drain terminal in the case of a MOSFET, collector or emitter terminal in the case of an IGBT, anode or cathode in the case of a diode, and so forth. The semiconductor die 100 may be configured as a so-called vertical device, wherein the load terminals of the semiconductor die 100 are provided on opposite facing main and rear surfaces of the semiconductor die 100 and the semiconductor die 100 is configured to conduct in a direction that is perpendicular to the main and rear surfaces. FIG. 1 shows an example of a vertical device configuration wherein the semiconductor die 100 comprises a second bond pad 106 disposed at a lower side, which may correspond to the opposite one of the source or drain terminal in the case of a MOSFET, collector or emitter terminal in the case of an IGBT, anode or cathode in the case of a diode, and so forth. In another embodiment, the semiconductor die 100 may be configured as a so-called lateral device, wherein each of the terminals of the semiconductor die 100 are provided on a single main surface of the semiconductor die 100 and the semiconductor die 100 is configured to conduct in a direction that is parallel to this main surface. The semiconductor die 100 may comprise additional bond pads disposed at the upper side 104 of the semiconductor die 100 that are not seen in FIG. 1. For example, the semiconductor die 100 may comprise an additional bond pad disposed at the upper side 104 that is configured as a control terminal (e.g., a gate terminal) in the case of a transistor device.

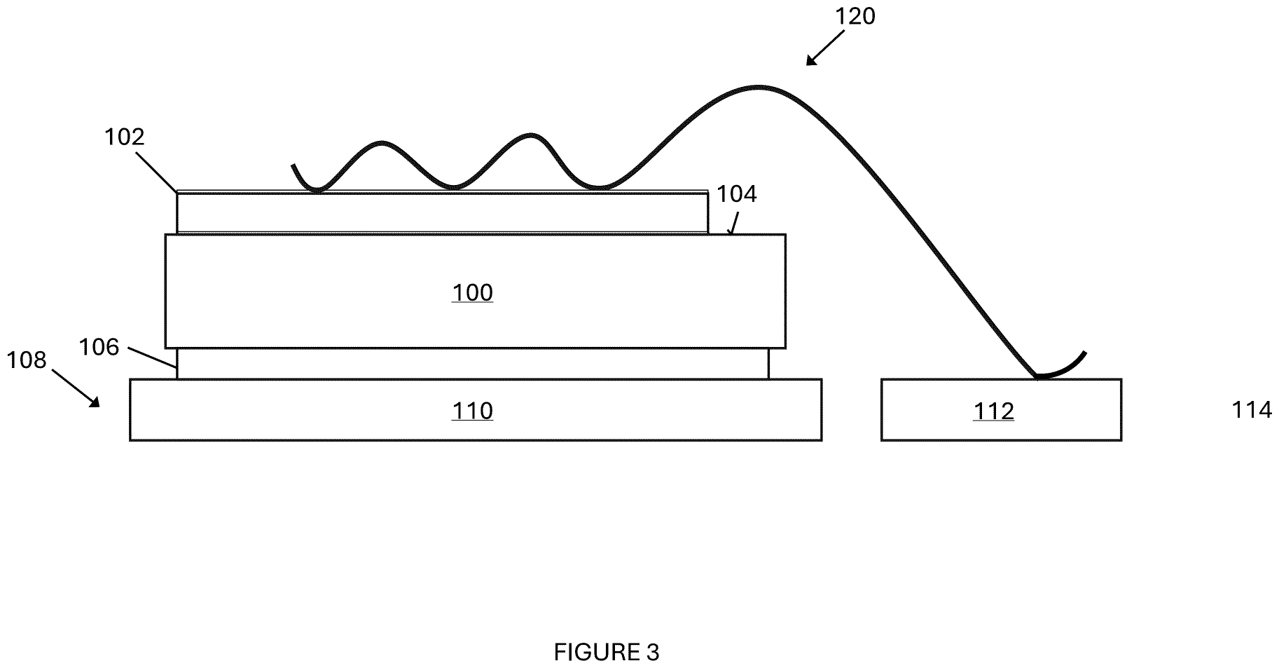

The method of forming a semiconductor package comprises providing a carrier 108 that comprises a die attach pad 110 and a landing pad 112. Generally speaking, the carrier 108 can be any structure that accommodates the mounting of one or more electronics devices (e.g., dies, passives, etc.) thereon and facilitates electrical interconnect between the mounted devices and the carrier 108 and/or with an external device. According to the depicted embodiment, the carrier 108 is configured as a power electronics substrate, which refers to an electronics carrier that is configured to accommodate one or more power devices and provide a thermally conductive heat dissipation path for these devices. Examples of power electronics substrates include DBC (direct bonded copper) substrates, IMS (insulated metal substrates) or AMB (active metal brazed) substrates. The power electronics substrate includes an upper metallization layer 114, a lower metallization layer 116, and an insulating substrate 118 arranged between the upper and lower metallization layers 114, 116. The insulating substrate 118 is formed from a thermally conductive and electrically isolating material, e.g., a ceramic material. The upper and lower metallization layers 114, 116 are formed from conductive metals comprising, e.g., Cu, Ni, Ag, Au, Pd, Pt, and alloys thereof. In the depicted embodiment, the die attach pad 110 and the landing pad 112 correspond to structured parts of the upper metallization layer 114. In another embodiment, the carrier 108 is configured as a PCB (printed circuit board). In that case, the carrier 108 may comprise electrically insulating substrate formed from laminate materials such as FR-4, FR-5, CEM-4, bismaleimide trazine (BT) resin, etc., and the die attach pad 110 and the landing pad 112 may correspond to structured parts of an upper metallization layer disposed on the electrically insulating substrate. In another embodiment, the carrier 108 is configured as a lead frame and may therefore be devoid of an electrically insulating substrate. An example of such an embodiment is further described below with reference to FIG. 3.

The method of forming the semiconductor package comprises mounting the semiconductor die 100 on the die attach pad 110 with the upper surface 104 and the bond pad 102 disposed thereon facing away from the carrier 108. The semiconductor die 100 may be mounted using any type of attachment technique, e.g., solder, sinter, glue, tape, etc. In the case of a vertical device, the semiconductor die 100 may be mounted such that the second bond pad 102 is electrically connected with the die attach pad 110, e.g., by a solder or sinter connection.

The method of forming the semiconductor package comprises attaching an electrical interconnect element 120 between the bond pad 102 and the landing pad 112. The electrical interconnect element 120 is an electrically conductive structure that forms an electrical connection between the bond pad 102 and the landing pad 112. The electrical interconnect element 120 may be formed from electrically conductive metals comprising, e.g., Cu, Ni, Ag, Au, Pd, Pt, and alloys thereof. The electrical interconnect element 120 may be attached to the bond pad 102 using any one of: mechanical pressure energy, or adhesive, e.g. solder, sinter, etc.

In the depicted embodiment, the electrical interconnect element 120 is configured as a bond wire. This bond wire may be a relatively thick bond wire that is configured for power applications. For example, the bond wire may have a diameter of at least 5 μm, at least 10 μm, at least 25 μm, at least 50 μm, at least 100 μm, at least 250, at least 500 μm or more. Separately or in combination, this bond wire may be a copper bond wire. As used herein, a copper bond wire refers to a bond wire that is formed of pure copper or an alloy comprising at least 90% copper by mass. An electrical interconnect element 120 that is configured as a bond wire may be attached to the bond pad 102 and the landing pad 112 using any type of wire bonding technique, e.g., wedge bonding, wedge-wedge bonding, ball bonding, wedge-ball bonding, laser welding, etc. These wire bonding techniques may include applying ultrasonic or laser energy and/or mechanical pressure to affix the electrical interconnect element 120 to the bond pad 102.

In other embodiments, the electrical interconnect element 120 may be configured as a metal clip or an interconnect ribbon. A metal clip refers to a relatively rigid structure that is formed from a planar sheet metal. Metal clips typically have a high current carrying capacity and/or thermal dissipation capacity in comparison to bond wires. An interconnect ribbon refers to an interconnect structure with a flattened cross-sectional footprint and a width that exceeds its thickness. Interconnect ribbons also offer a relatively high current carrying capacity and/or thermal dissipation capacity in comparison to bond wires while being more mechanically flexible than metal clips, thereby facilitating easier manipulation by machine tools.

The semiconductor die 100 is configured such that the bond pad 102 is formed from nanowires 122. Nanowires 122 refer to strands or material in form of a wire, i.e., an elongated and generally round element, which have a thickness measured along a cross-section of the wire in the nanometer range, e.g., between 10 nm to 2,000 nm. The description that the bond pad 102 is formed from nanowires 122 means that nanowires 122 exist throughout the complete volume of the bond pad 102. Further, the bond pad 102 is devoid of homogenous metal regions, e.g., regions of elemental metals or alloys thereof formed from conventional metallization techniques such as plating, sputtering, etc. As will be explained in further detail below, the nanowires 122 may be arranged loosely without any intermediary material separating them or alternatively may be arranged with an intermediary material binding them together.

The nanowires 122 are formed from an electrically conductive metal, e.g., Cu, Co, Ni, Pt, Au, Ag, and alloys thereof. The end-to-end length of the nanowires 122 may be in the range of 500 nm to 100 μm, for example. Each of the nanowires 122 in the group which forms the bond pad 102 may have the same or substantially the same length. The nanowires 122 may be formed by processes such as CVD (chemical vapor deposition, suspension, electrochemical deposition, VLS growth (VLS Vapor-liquid-solid method), and ion track technology, for example.

In the embodiment of FIG. 1, the bond pad 102 is devoid of an intermediary material between each of the nanowires 122. In this arrangement, the nanowires 122 are arranged loosely with the ambient environment separating the nanowires 122 from each other. The nanowires 122 may be arranged in a lawn-like arrangement, wherein the nanowires 122 extend mainly perpendicular to the upper side 104 of the semiconductor die 100. Thus, the thickness of the bond pad 102 may correspond roughly to the length of the nanowires 122. Generally speaking, the thickness of the bond pad 102 may be between 500 nm to 100 μm. The nanowires 122 in this arrangement are not necessarily exactly perpendicular and as a result may cross-cross with one another. For example, the nanowires 122 may be loosely intertwined and/or woven with one another.

Advantageously, a bond pad 102 formed by nanowires 122 facilitates higher thickness values without the drawbacks of solid metal structures, such as delamination, wafer bow, cracking, etc. The nanowire structure results in increased elasticity and malleability in comparison to bond pads from solid metal structures. This reduces stress on the semiconductor die 100 in comparison to corresponding solid metal structures under thermal compressive stresses. In embodiments, the bond pad 102 is least 2 μm thick, at least 5 μm thick, at least 10 μm thick, or at least at least 25 μm thick. Separately or in combination, a ratio between thickness of the bond pad 102 and a thickness of the semiconductor die 100 is at least 60%.

A further advantage of a bond pad 102 formed by nanowires 122 is that it can be combined with electrical interconnect elements 120 that are formed from a relatively hard material and/or electrical interconnect elements 120 that are attached using significant amounts of mechanical pressure without risk of cracking the bond pad 102. The compressibility of the bond pad 102 absorbs pressure and may conform to the contours of a hard electrical interconnect element 120 that is applied with mechanical pressure, e.g., from a wire bonding process. Generally speaking, copper-based electrical interconnect elements 120 are preferred in power electronics applications over other metals such as aluminum-based electrical interconnect elements 120. However, the high degree of hardness of copper in comparison to other metals requires increased mechanical pressure to effectuate an attachment in a pressure-based attachment technique, such as wire bonding. In embodiments, the electrical interconnect element 120 is a copper bond wire that is at least 1 μm thick, at least 2 μm thick, at least 5 μm thick, at least 10 μm thick, at least 25 μm thick, at least 50 μm thick, at least 100 μm thick, at least 250 μm, or at least 500 μm. Separately or in combination, a ratio between thickness of the bond pad 102 and a thickness of the electrical interconnect element 120 configured as a copper bond wire at least 10%. Separately or in combination, the electrical interconnect element 120 can be a copper bond wire that is attached to the bond pad 102 using a technique that involves mechanical pressure, e.g., wedge bonding, wedge-wedge bonding, ball bonding, wedge-ball bonding, etc.

After performing the steps for forming the semiconductor package as described above, further processing steps may be performed to complete the semiconductor package. These processing steps may include encapsulation steps whereby an electrically insulating encapsulant material is formed around the assembly comprising the carrier 108 and the semiconductor die 100. The completed semiconductor package may be a so-called power module. In that case, the carrier 108 may be arranged within a housing and (optionally) attached to a baseplate. This housing may be filled with a potting compound, such as silicone gel, which is hardened by a curing process.

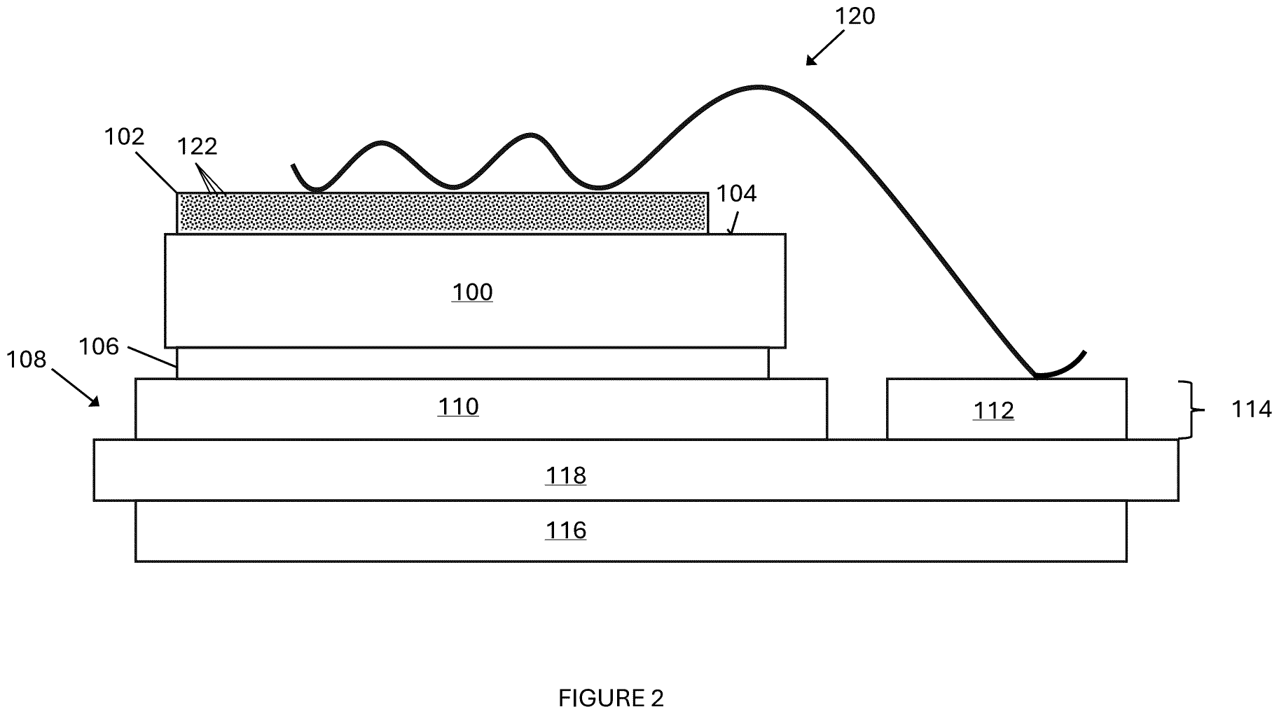

Referring to FIG. 2, a semiconductor package is formed, according to another embodiment. In the embodiment of FIG. 2, the bond pad 102 is formed from a group of nanowires 122 that are sintered together. Thus, in a difference with the previously described embodiment of FIG. 1, the space between the nanowires 122 is filled by sintering material, which acts as a binding agent and forms a monolithic structure with a compressed arrangement of the nanowires 122.

The bond pad 102 may be formed according to the following technique. Initially, the nanowires 122 may be formed on the upper side 104 of the semiconductor die 100 without an intermediary material between each of the nanowires 122, e.g., in a lawn-like arrangement in a similar manner as described above. The end-to-end length of the nanowires 122 may be in the range of 500 nm to 100 μm, for example. Subsequently, a sinter paste is applied on the nanowires 122. In general, the sinter paste can be any type of paste suitable for sintering comprising, e.g., Ag, Au, Cu, etc. Subsequently, a sintering process is performed whereby the temperature of the ambient environment is raised but maintained below the melting point of the metal which forms the nanowires 122. Optionally, mechanical pressure may be applied at this time as well. This process induces a reaction whereby the particles from the nanowires 122 diffuse into sinter paste, thereby compacting and reducing the porosity of the structure. The thickness of the bond pad 102 may be reduced, e.g., by 25% to 75% by the sintering process. In embodiments, the bond pad 102 formed from a group of nanowires 122 that are sintered together may have a thickness of between 1 μm and 12 μm. While denser than the previously described embodiment, the bond pad 102 formed from formed from a group of nanowires 122 that are sintered together is nevertheless compressible, thus making it possible to achieve the benefits described above with respect to thickness and mitigation of wafer bow. Moreover, the bond pad 102 formed from formed from a group of nanowires 122 may be well suited for pressure-based attachment process, such as the above-described wire bonding process, wherein the sintered structure conforms to and binds with the bond wire. Accordingly, the bond pad 102 may be used in combination with the interconnect elements and attachment techniques as described above while providing the same advantages with respect to interconnect element thickness, composition, and attachment technique as described above.

According to an embodiment, mounting the semiconductor die 100 on the die attach pad 110 comprises a sintering process and the sintering process concurrently attaches the semiconductor die 100 with the die attach pad 110 and bonds the group of nanowires 122 together. That is, a common processing step is used to both mount the semiconductor die 100 and create the structure of the bond wire comprising nanowires 122 that are sintered together. The sinter paste used to mount the semiconductor die 100 on the die attach pad 110 may optionally be the same as the sinter paste used to sinter the nanowires 122. In any case, a common annealing step may be performed that induces a sinter reaction to fuse a lower side bond pad 102 of the semiconductor die 100 with the die attach pad 110 and fuses the nanowires 122 with the sinter paste in the bond pad 102 disposed on the upper side 104 of the semiconductor die 100.

Referring to FIG. 3, a semiconductor package is formed, according to another embodiment. The semiconductor package comprises a bond pad 102 formed from a group of nanowires 122. The bond pad 102 may have any one of the configurations as described above. Thus, the bond pad 102 may be devoid of an intermediary material between each of the nanowires 122, e.g., as described with reference to FIG. 1, or may be formed from a group of nanowires 122 that are sintered together, e.g., as described with reference to FIG. 3.

In the embodiment of FIG. 3, the carrier 108 is configured as a lead frame. This lead frame may be formed from electrically conductive metals such as copper, aluminum, nickel, silver, palladium, gold, etc., and alloys thereof. The lead frame may comprise a core metal region that is formed from one or more of the above-mentioned electrically conductive metals and may optionally comprise one or more coatings formed on the core metal region that improve the surface properties of the lead frame, e.g., protection coatings, adhesion coatings, anti-corrosion coatings, etc. The lead frame may be formed from a uniform thickness sheet of metal that is processed using metal processing techniques such as stamping, bending, cutting, etching, etc.

In the embodiment of FIG. 3, the die attach pad 110 and the landing pad 112 correspond to separate portions of the lead frame. The lead frame may additionally comprise a peripheral ring (not shown) that supports the die attach pad 110 and the landing pad 112 before encapsulation, which is ultimately severed in a trimming step. The landing pad 112 may be connected with one or more leads that protrude from a package body and form externally accessible package terminals.

After forming the package assembly shown in FIG. 3, an encapsulation process may be performed on the assembly to form a package body of electrically insulating encapsulant material that encapsulates the semiconductor die 100 while permitting package contacts or leads to be externally accessible from the package body. The electrically insulating encapsulant material used to form the package body may be a plastic material formed from an organic resin such as an epoxy resin.

Although the present disclosure is not so limited, the following numbered examples demonstrate one or more aspects of the disclosure.

Example 1. A method of forming a semiconductor package, the method comprising: providing a semiconductor die that comprises a bond pad disposed at an upper side of the semiconductor die; providing a carrier that comprises a die attach pad and a landing pad; mounting the semiconductor die on the die attach pad with the bond pad facing away from the carrier; and attaching an electrical interconnect element between the bond pad and the landing pad, wherein the bond pad is formed from nanowires.

Example 2. The method of example 1, wherein the bond pad is formed from a group of nanowires that are sintered together.

Example 3. The method of example 2, wherein mounting the semiconductor die on the die attach pad comprises a sintering process, and wherein the sintering process concurrently attaches the semiconductor die with the die attach pad and bonds the group of nanowires together.

Example 4. The method of example 1, wherein the bond pad is devoid of an intermediary material between each of the nanowires.

Example 5. The method of example 1, wherein the electrical interconnect element is a bond wire.

Example 6. The method of example 1, wherein the bond wire is a copper bond wire that is at least 2 μm thick.

Example 7. The method of example 6, wherein attaching the electrical interconnect element comprises affixing the bond wire with the bond pad using mechanical pressure.

Example 8. The method of example 1, wherein the semiconductor die is a power transistor die, and wherein the bond pad is a load terminal of the power transistor die.

Example 9. The method of example 1, wherein the bond pad is at least 2 μm thick.

Example 10. A semiconductor package, comprising: a carrier that comprises a die attach pad and a landing pad; a semiconductor die that comprises a bond pad disposed at an upper side of the semiconductor die and is mounted on the die attach pad with the bond pad facing away from the carrier; and an electrical interconnect element attached between the bond pad and the landing pad, wherein the bond pad is formed from nanowires.

Example 11. The semiconductor package of example 10, wherein the bond pad is formed from a group of nanowires that are sintered together.

Example 12. The semiconductor package of example 11, wherein the bond pad is devoid of an intermediary material between each of the nanowires.

Example 13. The semiconductor package of example 11, wherein the electrical interconnect element is a bond wire.

Example 14. The semiconductor package of example 11, wherein the bond wire is a copper bond wire that is at least 2 μm thick.

Example 15. The semiconductor package of example 11, wherein the semiconductor die is a power transistor die, and wherein the bond pad is a load terminal of the power transistor die.

Example 16. The semiconductor package of example 11, wherein the bond pad is at least 5 μm thick.

Example 17. The semiconductor package of example 11, wherein the bond pad is at least 2 μm thick.

Example 18. The semiconductor package of example 11, wherein the carrier is a power electronics carrier.

Example 19. The semiconductor package of example 11, wherein the carrier is a lead frame.

Spatially relative terms such as “under,” “below,” “lower,” “over,” “upper” and the like, are used for ease of description to explain the positioning of one element relative to a second element. These terms are intended to encompass different orientations of the device in addition to different orientations than those depicted in the figures. Further, terms such as “first,” “second,” and the like, are also used to describe various elements, regions, sections, etc. and are also not intended to be limiting. Like terms refer to like elements throughout the description.

As used herein, the terms “having,” “containing,” “including,” “comprising” and the like are open-ended terms that indicate the presence of stated elements or features, but do not preclude additional elements or features. The articles “a,” “an” and “the” are intended to include the plural as well as the singular, unless the context clearly indicates otherwise.

Although the present disclosure is not so limited, the following numbered examples demonstrate one or more aspects of the disclosure.

With the above range of variations and applications in mind, it should be understood that the present invention is not limited by the foregoing description, nor is it limited by the accompanying drawings. Instead, the present invention is limited only by the following claims and their legal equivalents.

What is claimed is:

1. A method of forming a semiconductor package, the method comprising:
providing a semiconductor die that comprises a bond pad disposed at an upper side of the semiconductor die;
providing a carrier that comprises a die attach pad and a landing pad;
mounting the semiconductor die on the die attach pad with the bond pad facing away from the carrier; and
attaching an electrical interconnect element between the bond pad and the landing pad,
wherein the bond pad is formed from nanowires.

2. The method of claim 1, wherein the bond pad is formed from a group of nanowires that are sintered together.

3. The method of claim 2, wherein mounting the semiconductor die on the die attach pad comprises a sintering process, and wherein the sintering process concurrently attaches the semiconductor die with the die attach pad and bonds the group of nanowires together.

4. The method of claim 1, wherein the bond pad is devoid of an intermediary material between each of the nanowires.

5. The method of claim 1, wherein the electrical interconnect element is a bond wire.

6. The method of claim 1, wherein the bond wire is a copper bond wire that is at least 2 μm thick.

7. The method of claim 6, wherein attaching the electrical interconnect element comprises affixing the bond wire with the bond pad using mechanical pressure.

8. The method of claim 1, wherein the semiconductor die is a power transistor die, and wherein the bond pad is a load terminal of the power transistor die.

9. The method of claim 1, wherein the bond pad is at least 2 μm thick.

10. A semiconductor package, comprising:
a carrier that comprises a die attach pad and a landing pad;
a semiconductor die that comprises a bond pad disposed at an upper side of the semiconductor die and is mounted on the die attach pad with the bond pad facing away from the carrier; and
an electrical interconnect element attached between the bond pad and the landing pad,
wherein the bond pad is formed from nanowires.

11. The semiconductor package of claim 10, wherein the bond pad is formed from a group of nanowires that are sintered together.

12. The semiconductor package of claim 10, wherein the bond pad is devoid of an intermediary material between each of the nanowires.

13. The semiconductor package of claim 10, wherein the electrical interconnect element is a bond wire.

14. The semiconductor package of claim 10, wherein the bond wire is a copper bond wire that is at least 2 μm thick.

15. The semiconductor package of claim 10, wherein the semiconductor die is a power transistor die, and wherein the bond pad is a load terminal of the power transistor die.

16. The semiconductor package of claim 10, wherein the bond pad is at least 5 μm thick.

17. The semiconductor package of claim 10, wherein the bond pad is at least 2 μm thick.

18. The semiconductor package of claim 10, wherein the carrier is a power electronics carrier.

19. The semiconductor package of claim 10, wherein the carrier is a lead frame.
